(19) United States
(12) Patent Application Publication
(10) Pub. No.: US 2009/0199058 A1
(43) Pub. Date: Aug. 6, 2009

(54) Programmable memory with reliability testing of the stored data

(76) Inventors: Christoph Seidl, Graz (AT); Manfred Oswald, Graz (AT); Axel Reithofer, Graz (AT); Viktor Kahr, Hart bei Graz (AT)

Correspondence Address: SLATER & MATSIL LLP, 17950 PRESTON ROAD, SUITE 1000, DALLAS, TX, 75252, US

(21) Appl. No.: 12/026,687

(22) Filed: Feb. 6, 2008

(51) Int. Cl. G11C 29/10; G06F 11/263

(52) U.S. Cl. 714/719; 714/E11.177

(57) ABSTRACT

The invention relates, inter alia, to a method for testing a programmable memory cell having a particular memory state, the method involving the following steps of: applying a first read signal to the memory cell, with the result that the memory cell provides a first memory signal which represents its memory state; comparing the first memory signal with a threshold value in order to obtain a first comparison result; applying a second read signal to the memory cell, with the result that the memory cell provides a second memory signal which represents its memory state; comparing the second memory signal with the threshold value in order to obtain a second comparison result; assessing the integrity of the memory state using the two comparison results.

### TECHNICAL FIELD

The present invention relates to the field of programmable nonvolatile memories, for example, “programmable read only memories” (PROMs).

### BACKGROUND

Programmable memory cells, for example PROMs, EPROMs, EEPROMs or flash memories, allow individual information to be stored in a semiconductor chip. In this case, the memory can be programmed differently depending on the type of memory. For example, in the case of an EPROM cell, a “floating gate” of a MOSFET is charged in order to program the memory cell to the logic state “1”. However, a simple PROM cell may also have a variable resistor which, for example, has a high-value resistance (for example in the megohm range) in the programmed state, whereas it has a low-value resistance (for example in the kilohm range or less) in the unprogrammed state. Such a variable resistor can be implemented, for example, using a so-called “fuse” (fusible conductive link) which is or is not fused during programming of the memory cell depending on the Boolean value to be assumed by the memory cell.

When reading the memory cell, the state of the memory cell (for example the resistance of a “fuse” of a PROM cell) is compared with a threshold value. The comparison result can be used as a basis for deciding whether the Boolean value “1” or “0” is stored in the memory cell. However, the state of the memory cell itself is not binary but rather can assume any desired intermediate states between the values of “logic 0” and “logic 1”. One example of the “state of a memory cell” is the abovementioned nonreactive resistance of the “fuse”. This state is only converted to a binary value by comparing it with a reference value when reading the memory cell. The logic value (“0” or “1”) to which the stored state of the memory cell is converted during reading thus depends on the reference value.

It appears that the entire system comprising the memory cell plus the evaluation circuit can be subjected to a certain amount of drift; the entire system is subjected to a modification process as it were. The causes of this may be, for example, fluctuating thermal or mechanical loads which act on the memory cell and the evaluation circuit during operation. Over the course of time, this may result in a change in the Boolean value read from the memory cell. For example, the resistance of a “fuse” may change slowly until the threshold value used for reading the memory cell is exceeded and the value read from the memory cell changes from “0” to “1” or vice versa.

The above-described slow change in the memory cells is problematic, in particular, in applications which require a high level of reliability of the memories used. One possible way of increasing the reliability is redundant storage of data, in which redundantly stored information is regularly compared and errors can be detected if the redundantly stored information no longer matches. However, errors are not completely excluded even when redundant memories are used since the redundant memory may also be subjected to the abovementioned modification process.

Consequently, there is a need for a method for testing a programmed memory cell, which method can be used to detect the abovementioned modification processes and can thus be used to increase the reliability of the memory cell.

### SUMMARY

One example of the invention relates to a method for testing a programmable memory cell having a particular memory state. The method involves: applying a first read signal to the memory cell, with the result that the memory cell provides a first memory signal which represents its memory state; comparing the first memory signal with a threshold value in order to obtain a first comparison result; applying a second read signal to the memory cell, with the result that the memory cell provides a second memory signal which represents its memory state; comparing the second memory signal with the threshold value in order to obtain a second comparison result; assessing the integrity of the memory state using the two comparison results.

Another example of the invention relates to a method which involves: applying a read signal to the memory cell, with the result that the memory cell provides a memory signal which represents its memory state; comparing the memory signal with a first threshold value in order to obtain a first comparison result; comparing the memory signal with a second threshold value in order to obtain a second comparison result; assessing the integrity of the memory state using the two comparison results.

A third example of the invention relates to a method which involves: applying a first read signal to the memory cell, with the result that the memory cell provides a first memory signal which represents its memory state; comparing the first memory signal with a first threshold value in order to obtain a first comparison result; applying a second read signal to the memory cell, with the result that the memory cell provides a second memory signal which represents its memory state; comparing the second memory signal with a second threshold value in order to obtain a second comparison result; assessing the integrity of the memory state using the two comparison results.

The invention also relates to a memory arrangement having a memory cell and a reading device, which arrangement is designed: to apply a first read signal to the memory cell, with the result that the memory cell provides a first memory signal which represents its memory state; to compare the first memory signal with a threshold value in order to obtain a first comparison result; to apply a second read signal to the memory cell, with the result that the memory cell provides a second memory signal which represents its memory state; to compare the second memory signal with the threshold value in order to obtain a second comparison result; and to assess the integrity of the memory state using the two comparison results.

### BRIEF DESCRIPTION OF THE FIGURES

The following figures and the further description are intended to assist with better understanding of the invention. The elements in the figures are not necessarily to be understood as a restriction, rather importance is placed on illustrating the principle of the invention. In the figures, identical reference symbols denote corresponding parts.

FIG. 1 is a block diagram of a memory arrangement having a memory cell and a reading device for the memory cell;

FIG. 2 is a diagram which is used to explain one example of the inventive method for testing a programmable memory cell;

FIG. 3 is a diagram which is used to explain another example of the inventive method for testing a programmable memory cell;

FIG. 4 shows the arrangement from FIG. 1 in more detail; the memory cell is an EPROM memory cell in this example;

FIG. 5 shows the arrangement from FIG. 1 in more detail; the memory cell is a PROM cell in the form of a “fuse” in this example;

FIGS. 6a-6d are diagrams for explaining the method of operation of the arrangement from FIG. 5;

FIGS. 7a-7b are diagrams for explaining the method of operation of the arrangement from FIG. 5;

FIG. 8 is an alternative exemplary embodiment to the example from FIG. 5;

FIGS. 9a-9b are diagrams for explaining the method of operation of the arrangement from FIG. 8.

### DETAILED DESCRIPTION

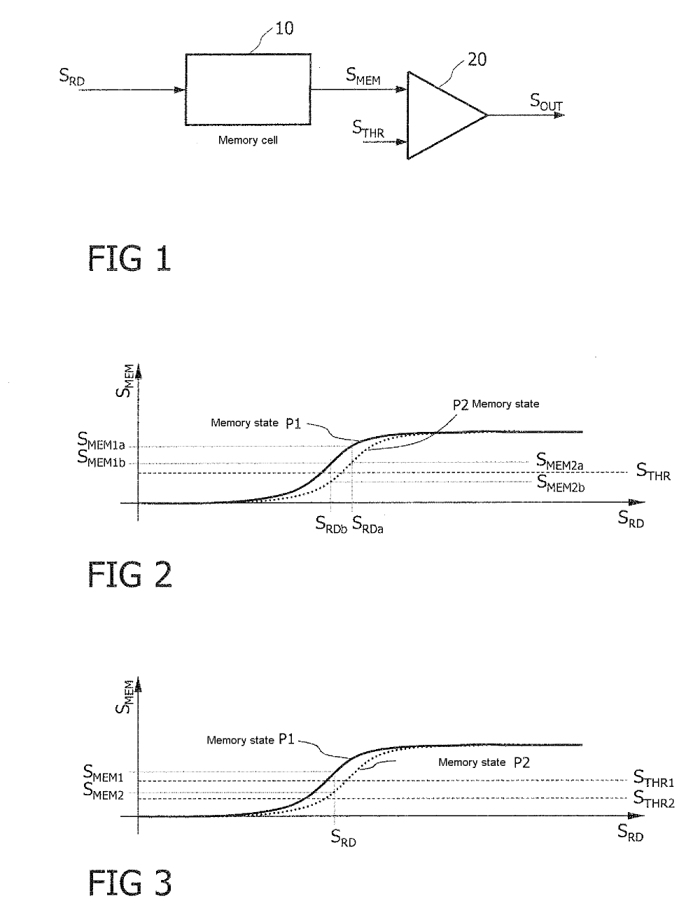

FIG. 1 shows an arrangement having a memory cell 10 and a reading device 20 which is connected to the latter. It is assumed, for the further considerations, that the memory cell 10 is programmed and has a memory state P1 or P2 which corresponds either to a logic level “0” or to a logic level “1”. In order to read the memory cell, a read signal S_{RD} is applied to the memory cell. In response to this, the memory cell provides the reading device 20 with a memory signal S_{MEM}. The reading device 20 is designed to compare the memory signal S_{MEM} with at least one threshold value S_{THR}. The comparison result S_{OUT} represents the logic value (“0” or “1”) which is stored in the memory cell and is provided in the form of a logic signal S_{OUT} at the output of the reading device 20.

The method of operation of the arrangement illustrated in FIG. 1 is explained below with reference to FIGS. 2 and 3. According to one example of the present invention, two or more read signals S_{RDa}, S_{RDb} with different signal levels are sequentially applied to the memory cell 10. In response to this, the memory cell in the state P1 provides correspondingly different memory signals S_{MEM1a} and S_{MEM1b}. These two memory signals S_{MEM1a} and S_{MEM1b} are sequentially compared with the threshold value S_{THR}. It can be seen in FIG. 2 that both memory signals S_{MEM1a} and S_{MEM1b} are above the threshold value S_{THR} in the case of a memory state PI which represents the logic value “1”, for example. The memory state P1 represents the desired state of an intact memory cell. Such a desired state should be present after the production process and the programming process have been concluded in the case of a new memory cell, for example.

The memory state P2 represents a memory state which is slightly modified in comparison with the memory state P1. This modification may be produced, for example, by the drift phenomena (mentioned initially) on account of thermal or mechanical loading over the course of time. The effect of this modification can likewise be seen in FIG. 2. The memory signals S_{MEM2a} and S_{MEM2b} which result on account of the read signals S_{RDa} and S_{RDb} are on different sides of the threshold value S_{THR} in the case of a memory state P2. If the memory cell is thus read using a read signal S_{RDa}, the resultant memory signal S_{MEM2a} is above the threshold value S_{THR}. If the memory cell is read using the read signal S_{RDb}, the resultant memory signal S_{MEM2b} is below the threshold value S_{THR}. It follows from this that a stored logic value “1” or “0” is detected on the basis of the memory state P2 of the memory cell 10 depending on the level of the applied read signal.

If the comparisons of the different memory signals S_{MEM2a} and S_{MEM2b} with the threshold value S_{THR} result in different results, it can be inferred from this that the memory state of the relevant memory cell no longer corresponds to the desired state P1 and consequently the integrity of the memory cell is no longer ensured. In addition, the originally programmed desired state can also be used for this comparison provided that the information relating to said state is available. This method for testing the memory cell can also be carried out with more than two read signals. A measure of the “deterioration” of the memory state can also be determined with suitably fine graduation of the level of the read signals.

FIG. 3 illustrates an alternative or an addition to the method described using FIG. 2. A desired memory state P1 and a “deteriorated” memory state (“degraded memory state”) P2 are considered in this case too. However, in contrast to the example from FIG. 2, only a single read signal S_{RD} is applied to the memory cell, said signal resulting in a memory signal S_{MEM1} or a memory signal S_{MEM2} depending on the memory state (P1 or P2). In the present case, the memory signals are compared with at least two threshold values S_{THR1} and S_{THR2}. In the case of the intact memory state P1, the corresponding memory signal S_{MEM1} is above the two threshold values S_{THR1} and S_{THR2}. In the case of the deteriorated memory state P2, the corresponding memory signal S_{MEM2} is between the two threshold values S_{THR1} and S_{THR2}. “0” or “1” is obtained as the result for the stored Boolean value depending on the threshold value (S_{THR1} or S_{THR2}) used to carry out the comparison in the evaluation device 20. With an appropriately selected level of the threshold values S_{THR1} and S_{THR2}, it is possible, in a manner similar to that in the example from FIG. 2, to infer the integrity of the memory cell from the comparison results and to take corresponding measures, if necessary, in order to prevent further malfunctions on account of the defective memory cell. This variant which is described using FIG. 3 can be extended to the use of more than two threshold values. It goes without saying that the examples described using FIG. 2 and FIG. 3 can also be combined.

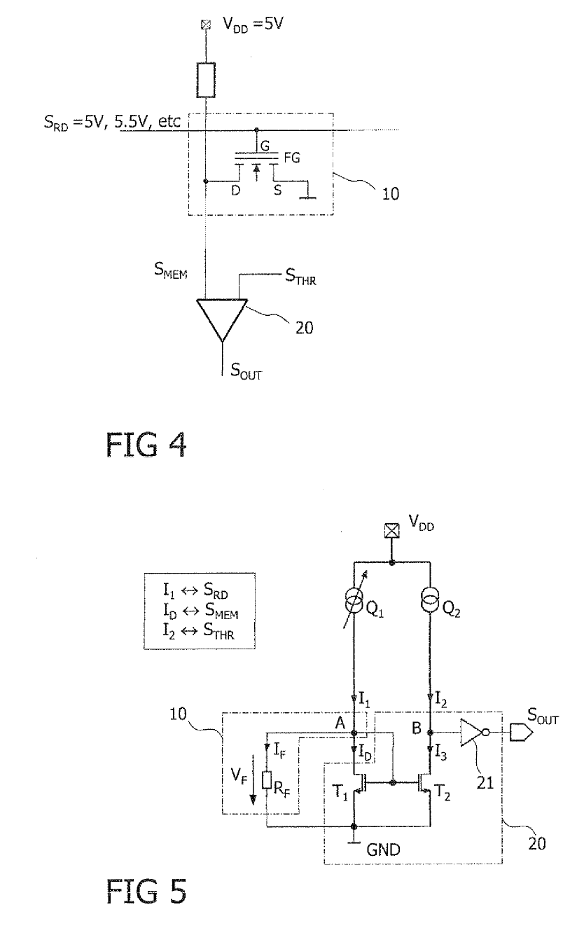

FIG. 4 shows one example of the arrangement from FIG. 1, an EPROM memory cell being used as the memory cell 10. As is known, an EPROM memory cell 10 comprises a field effect transistor with a gate electrode G, a “floating gate” FG, a drain electrode D and a source electrode S. The source electrode S is connected to a ground connection GND, and the drain electrode is connected to a supply voltage V_{DD} of typically 5 volts via a pull-up resistor. The read signal S_{RD} is supplied to the gate electrode G. The evaluation device 20 is likewise connected to the drain electrode and is designed to compare the memory signal S_{MEM} provided at the drain electrode with the threshold value S_{THR} and to provide a logic level S_{OUT}, which corresponds to the comparison result, at the output of the reading device 20. When programming the EPROM cell, a certain amount of charge is applied to the floating gate, thus changing the transfer function of the field effect transistor. In the present case, a particular charge on the floating gate corresponds, for example, to the desired memory state P1 from the examples of FIGS. 2 and 3. In a manner corresponding to the methods explained using FIGS. 2 and 3, the memory cell can now be read using different read signals S_{RDa}, S_{RDb}, etc. and the resultant different memory signals S_{MEM1a}, S_{MEM1b}, etc. can be compared with the threshold value S_{THR}. Alternatively, only one read signal S_{RD} of 5 volts, for example, can also be used, the resultant memory signal S_{MEM} being compared with different threshold values S_{THR1}, S_{THR2}, etc. As explained above, the integrity of the EPROM cell can be inferred from the comparison result. It is also possible to combine the examples from FIGS. 2 and 3 irrespective of the type of memory used.

FIG. 5 shows another detailed exemplary embodiment of the arrangement from FIG. 1. A “fuse” (symbolized by the nonreactive resistor R_{F}), as can be used in a PROM, for example, is used as the memory cell in the present case. The fuse has a high-value resistance (severed fuse) or a low-value resistance (unsevered fuse) depending on its programming. In this case, the reading device 20 comprises a current mirror comprising the transistors T₁ and T₂, the drain-source path of the transistor T₁ being connected in parallel with the fuse R_{F}. In order to be read, the memory cell is driven using a current I₁ which is generated by a variable current source Q₁. In the present example, the current I₁ corresponds to the read signal S_{RD}. The load path of the transistor T₁ and the fuse R_{F} form a current divider. In the case of a severed fuse, most of the current I₁ will flow through the transistor T₁, with the result that the drain current I_{D} of the transistor T₁ is approximately equal to the current I₁. In contrast, in the case of an unsevered fuse, a considerable part of the current I₁ will flow through the fuse and the drain current I_{D} will be correspondingly lower. In the present case, the current mirror is used as a comparator, the threshold value being determined by the level of the current I₂, which is generated by a current source Q₂ which is connected to the drain connection of the transistor T₂, and the transformation ratio of the current mirror T₁, T₂. In the case of an unsevered fuse, the drain current I_{D}, which in the present case corresponds to the memory signal S_{MEM} from the preceding examples, is approximately equal to the current I₁. When the transformation ratio of the current mirror is 1:1, the current I₃ (drain current of T₂) should be equal to the drain current I_{D} of T₁. If, however, the current I₂ generated by the current source Q₂ is lower, the drain potential (circuit node B) of the transistor T₂ assumes a low value, that is to say a low level, which is inverted by the inverter 21 which is connected to the circuit node B, with the result that an unsevered fuse results in a high level of the output signal S_{OUT}. In the case of a severed fuse, a corresponding low level of the output signal S_{OUT} results at the output.

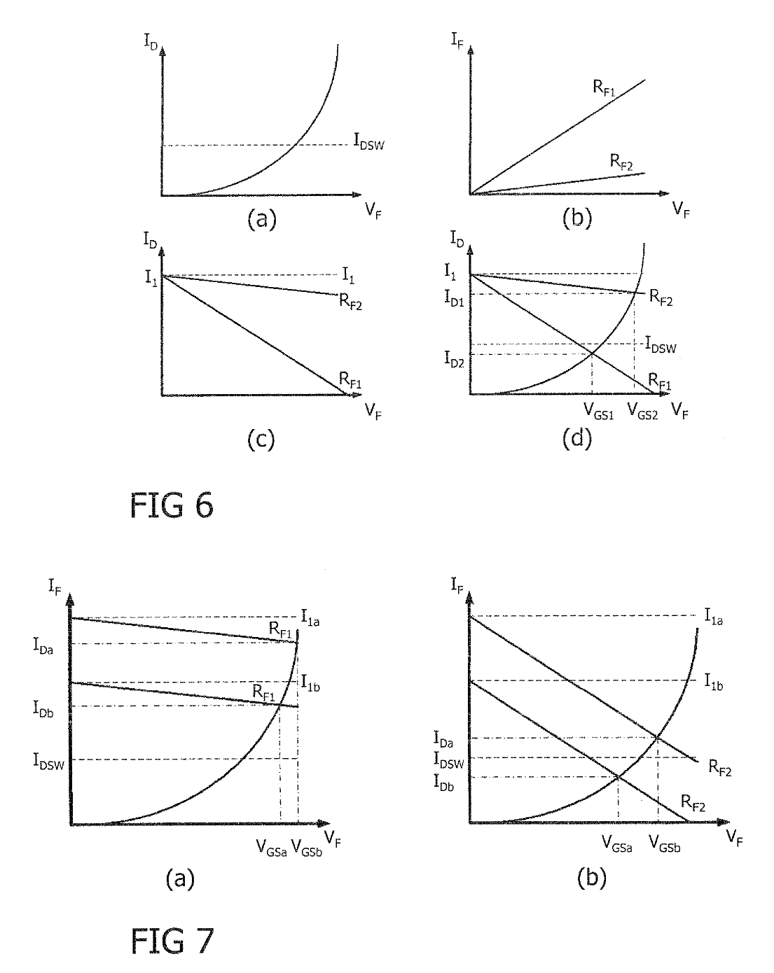

In order to explain the method of operation of the circuit from FIG. 5, FIGS. 6a to 6d show the characteristic curves of the transistor T₁ (FIG. 6a), of the fuse (FIG. 6b) and of the parallel circuit comprising the fuse and the transistor (FIG. 6c). The respective operating points of the parallel circuit comprising the transistor and the fuse can be gathered from FIG. 6d, the fuse being represented by the resistances R_{F1} (memory state P1) and R_{F2} (memory state P2). The threshold value I_{DSW} depicted for the drain current I_{D} results from the current I₂ of the current source Q₂ and the transformation ratio of the current mirror.

FIG. 7 uses the characteristic curves of the parallel circuit comprising the transistor and the fuse to describe the method of operation of the memory arrangement from FIG. 5 in accordance with the method described in FIG. 2. Different read signals (current I₁ₐ and I_{1b}) are applied to the fuse by varying the current I₁. Different drain currents I_{Da} and I_{Db} are produced as the result, the respective drain currents depending on the resistance R_{F1} of the fuse. If the resistance changes from a value R_{F1} to a value R_{F2}, the resultant drain currents I_{Da} and I_{Db} also change. FIG. 7a shows the intact desired memory state P1 in which both drain currents I_{Da} and I_{Db} are above the threshold value I_{DSW}, and FIG. 7b shows a deteriorated memory state P2 which, according to the method described in FIG. 2, can be detected by virtue of one drain current being above the threshold value and one drain current being below the threshold value I_{DSW}.

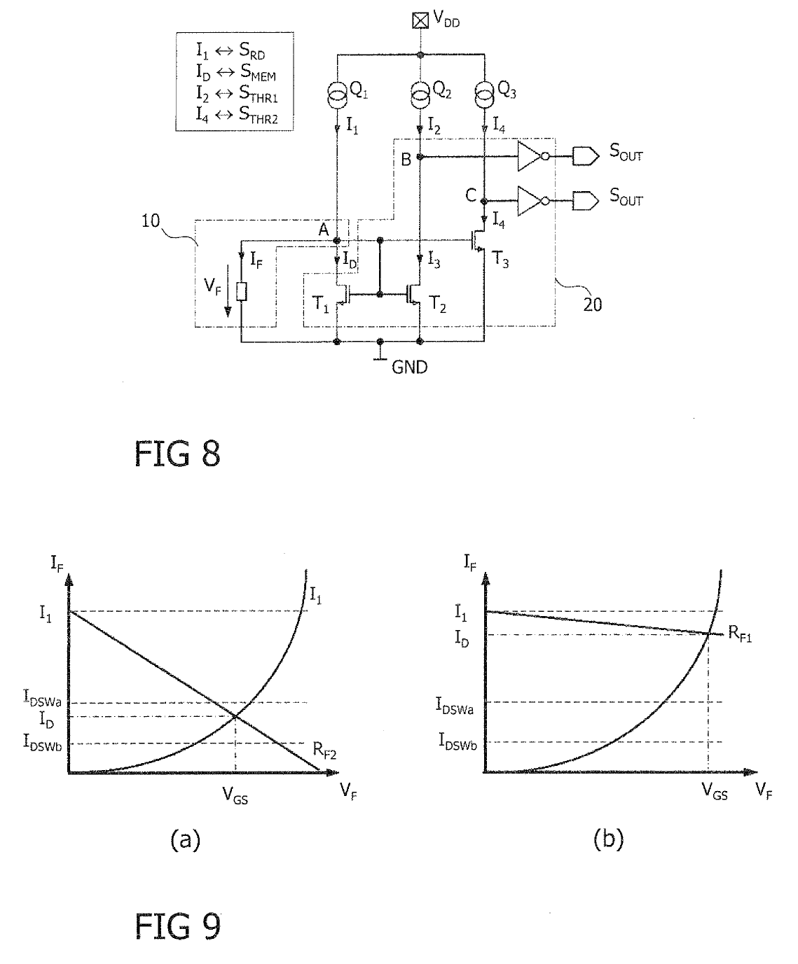

FIG. 8 shows an alternative exemplary embodiment to the circuit from FIG. 5. This example essentially corresponds to the example from FIG. 5, the current mirror having a third transistor T₃ whose drain connection is connected to a third current source Q₃ which provides a current I₄. The method of operation of this example corresponds to the principle explained using FIG. 3. As explained above, the drain current through the transistor T₁ assumes a particular value depending on the state of the fuse, which value is compared with a threshold value determined by the current I₂. In addition to the example from FIG. 5, a comparison with a second threshold value, which is determined by the current I₄, also takes place in the circuit from FIG. 8. In this case, the current mirrors comprising the transistors T₁ and T₂ and T₁ and T₃ again operate as comparators in a manner similar to that in the example from FIG. 5.

The method of operation of the example illustrated in FIG. 8 is explained in more detail using the characteristic curves illustrated in FIGS. 9a and 9b. FIG. 9a shows the case of a fuse in a deteriorated memory state P2, in which the drain current I_{D} through the transistor T₁ is between the threshold values I_{DSWa} and I_{DSWb}, the threshold values I_{DSWa} and I_{DSWb} being determined by the currents I₂ and I₄ and the transformation ratio between the transistors T₁ and T₂ and T₁ and T₃. In the example of FIG. 9b, the drain current I_{D} is above the two threshold values, from which it can be inferred that the integrity of the memory cell under consideration is intact.

1. A method for testing a programmable memory cell having a particular memory state, the method comprising:
applying a first read signal to the memory cell causing the memory cell to provide a first memory signal that represents its memory state;
comparing the first memory signal with a threshold value in order to obtain a first comparison result;
applying a second read signal to the memory cell so that the memory cell provides a second memory signal that represents its memory state;
comparing the second memory signal with the threshold value in order to obtain a second comparison result; and
assessing the integrity of the memory state using the two comparison results.

2. A method for testing a programmable memory cell having a particular memory state, the method comprising:
applying a read signal to the memory cell so that the memory cell provides a memory signal that represents its memory state;
comparing the memory signal with a first threshold value in order to obtain a first comparison result;
comparing the memory signal with a second threshold value in order to obtain a second comparison result; and
assessing the integrity of the memory state using the two comparison results.

3. The method as claimed in claim 1, further comprising:
applying a further read signal to the memory cell so that the memory cell provides a further memory signal that represents its memory state; and
comparing the further memory signal with the threshold value in order to obtain a further comparison result, the further comparison result additionally being taken into account when assessing the integrity of the memory cell.

4. The method as claimed in claim 2, further comprising:
comparing the memory signal with a further threshold value in order to obtain a further comparison result, the further comparison result additionally being taken into account when assessing the integrity of the memory cell.

5. The method as claimed in claim 1, wherein the memory cell is a PROM cell, an EPROM cell or an EEPROM cell.

6. The method as claimed in claim 1, wherein assessing the integrity comprises:
determining a positive assessment of the integrity of the memory cell when both comparisons provide the same result, and
determining a negative assessment of the integrity of the memory cell when both comparisons provide different results.

7. A memory arrangement having a memory cell and a reading device, the arrangement being designed
to apply a first read signal to the memory cell so that the memory cell provides a first memory signal that represents its memory state;
to compare the first memory signal with a threshold value in order to obtain a first comparison result;
to apply a second read signal to the memory cell so that the memory cell provides a second memory signal that represents its memory state;
to compare the second memory signal with the threshold value in order to obtain a second comparison result; and
to assess the integrity of the memory state using the two comparison results.

8. A memory arrangement having a memory cell and a reading device, the arrangement being designed
to apply a read signal to the memory cell so that the memory cell provides a memory signal which represents its memory state;
to compare the memory signal with a first threshold value in order to obtain a first comparison result;
to compare the memory signal with a second threshold value in order to obtain a second comparison result; and
to assess the integrity of the memory state using the two comparison results.

9. The memory arrangement as claimed in claim 7, wherein the memory cell is a PROM cell, an EPROM cell or an EEPROM cell.

10. A method for testing a programmable memory cell having a particular memory state, the method comprising:
applying a first read signal to the memory cell so that the memory cell provides a first memory signal that represents its memory state;
comparing the first memory signal with a first threshold value in order to obtain a first comparison result;
comparing the first memory signal with a second threshold value in order to obtain a second comparison result;
applying a second read signal to the memory cell so that the memory cell provides a second memory signal that represents its memory state;
comparing the second memory signal with the first threshold value in order to obtain a third comparison result;
comparing the second memory signal with a third threshold value in order to obtain a fourth comparison result; and
assessing the integrity of the memory state using the second and fourth comparison results.

11. The method as claimed in claim 10, further comprising:
comparing the first memory signal with a further threshold value in order to obtain a further comparison result; and/or
comparing the second memory signal with a further threshold value in order to obtain a further comparison result.

12. The method as claimed in claim 11, further comprising:
applying at least one third read signal to the memory cell so that the memory cell provides at least one third memory signal that represents its memory state; and
comparing the third memory signal with the first threshold value in order to obtain a further comparison result.

13. The method as claimed in claim 10, wherein assessing the integrity comprises:
determining a positive assessment of the integrity of the memory cell when at least a predefined number of comparisons provide the same result, and
determining a negative assessment of the integrity of the memory cell when the predefined number of comparisons do not provide the same result.

14. A method for testing a programmable memory cell having a particular memory state, the method comprising:
applying a first read signal to the memory cell so that the memory cell provides a first memory signal that represents its memory state;
comparing the first memory signal with a first threshold value in order to obtain a first comparison result;
applying a second read signal to the memory cell so that the memory cell provides a second memory signal that represents its memory state;
comparing the second memory signal with a second threshold value in order to obtain a second comparison result; and
assessing the integrity of the memory state using the first and second comparison results.

15. The method as claimed in claim 14, further comprising:
applying a third read signal to the memory cell so that the memory cell provides a third memory signal that represents its memory state; and
comparing the third memory signal with a third threshold value in order to obtain a third comparison result;
wherein assessing the integrity of the memory state uses the first, second and third comparison results.

16. The method as claimed in claim 15, further comprising:
applying a fourth read signal to the memory cell so that the memory cell provides a fourth memory signal that represents its memory state; and
comparing the fourth memory signal with a fourth threshold value in order to obtain a fourth comparison result;
wherein assessing the integrity of the memory state uses the first, second, third and fourth comparison results.

17. The method as claimed in claim 2, wherein the memory cell is a PROM cell, an EPROM cell or an EEPROM cell.

18. The memory arrangement as claimed in claim 8, wherein the memory cell is a PROM cell, an EPROM cell or an EEPROM cell.

19. The method as claimed in claim 16, wherein the memory cell is a PROM cell, an EPROM cell or an EEPROM cell.
